(19) United States
(12) Patent Application Publication
(10) Pub. No.: US 2025/0320430 A1
(43) Pub. Date: Oct. 16, 2025

(54) SEMICONDUCTOR TREATMENT LIQUID, TREATMENT METHOD FOR OBJECT TO BE TREATED, AND MANUFACTURING METHOD OF ELECTRONIC DEVICE

(71) Applicant: FUJIFILM CORPORATION, Tokyo (JP)

(72) Inventors: Yuta Shigenoi, Shizuoka (JP); Atsushi Mizutani, Shizuoka (JP)

(21) Appl. No.: 19/247,818

(22) Filed: Jun. 24, 2025

Related U.S. Application Data
(63) Continuation of application No. PCT/JP2024/001068, filed on Jan. 17, 2024.

(30) Foreign Application Priority Data
Feb. 7, 2023 (JP) 2023-016803
Dec. 21, 2023 (JP) 2023-215566

(51) Int. Cl. C11D 3/28; C11D 1/00; C11D 3/00; C11D 3/30; H01L 21/02

(52) U.S. Cl. CPC C11D 3/28; C11D 1/008; C11D 3/0047; C11D 3/30; H01L 21/02074; C11D 2111/22

(57) ABSTRACT

Provided is a semiconductor treatment liquid which has excellent anticorrosion properties with a metal and excellent cleanability for organic residues, in a case of being brought into contact with an object to be treated containing a metal, which has been subjected to a chemical mechanical polishing treatment. The semiconductor treatment liquid of the present invention contains a compound represented by Formula (1), and a pH of the semiconductor treatment liquid is more than 7.0.

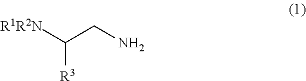

### CROSS-REFERENCE TO RELATED APPLICATIONS

This application is a Continuation of PCT International Application No. PCT/2024/001068 filed on Jan. 17, 2024, which claims priority under 35 U.S.C. § 119(a) to Japanese Patent Application No. 2023-016803 filed on Feb. 7, 2023 and Japanese Patent Application No. 2023-215566 filed on Dec. 21, 2023. The above applications are hereby expressly incorporated by reference, in their entirety, into the present application.

### BACKGROUND OF THE INVENTION

### 1. Field of the Invention

The present invention relates to a semiconductor treatment liquid, a treatment method for an object to be treated, and a manufacturing method of an electronic device.

### 2. Description of the Related Art

A semiconductor element is manufactured by forming a resist film on a laminate having, on a substrate, a metal film serving as a wiring line material, an etching stop layer, and an interlayer insulating layer, and performing a photolithography step. In the photolithography step, a method of etching or removing foreign substances on a surface of the substrate using a treatment liquid which dissolves a metal and/or an organic substance has been widely known.

In addition, in manufacturing of the semiconductor element, a chemical mechanical polishing (CMP) treatment in which a surface of a semiconductor substrate having a metal wire film, a barrier metal, an insulating film, or the like is flattened using a polishing slurry containing abrasive particles (for example, silica and alumina) or the like may be carried out.

In the CMP treatment, the abrasive particles to be used in the CMP treatment, a polished wiring line metal film, and/or a metal component derived from the barrier metal or the like easily remain on the surface of the semiconductor substrate after polishing. Therefore, after the CMP treatment, a step of removing these residues using a treatment liquid is generally performed.

As described above, in a semiconductor manufacturing process, the treatment liquid is used for treatments such as removal of unnecessary metal-containing substances, resist, and residues on the substrate. Hereinafter, such a treatment liquid used in the manufacturing process of the semiconductor element is also referred to as a semiconductor treatment liquid.

As the treatment liquid described above, for example, JP2010-174074A discloses a cleaning agent for a copper wire semiconductor, which contains a quaternary ammonium hydroxide, an amine, and water, and has a pH of 3.0 to 14.0.

### SUMMARY OF THE INVENTION

As a result of studying the treatment liquid specifically disclosed in JP2010-174074A, the present inventors have found that, in a case where the treatment liquid is brought into contact with an object to be treated containing a metal, which has been subjected to a chemical mechanical polishing treatment, it is not possible to achieve both anticorrosion properties of suppressing dissolution of the metal and cleanability for organic residues, and further improvement is required.

Therefore, an object of the present invention is to provide a semiconductor treatment liquid which has excellent anticorrosion properties with a metal and excellent cleanability for organic residues, in a case of being brought into contact with an object to be treated containing a metal, which has been subjected to a chemical mechanical polishing treatment.

Another object of the present invention is to provide a treatment method for an object to be treated, using the treatment liquid, and a manufacturing method of an electronic device.

As a result of conducting an extensive investigation to achieve the objects, the present inventors have found that the objects can be achieved by the following constitution.

[1]A semiconductor treatment liquid comprising:
a compound represented by Formula (1) described later,
in which a pH of the semiconductor treatment liquid is more than 7.0.

[2] The semiconductor treatment liquid according to [1],
in which the pH is 10.0 or more.

[3] The semiconductor treatment liquid according to [1] or [2], further comprising:
at least one purine compound selected from the group consisting of purine and a purine derivative.

[4] The semiconductor treatment liquid according to [3],
in which the purine compound includes at least one compound selected from the group consisting of a compound represented by Formula (C5) described later and a compound represented by Formula (C7) described later.

[5] The semiconductor treatment liquid according to any one of [1] to [4], further comprising:
at least one compound selected from the group consisting of a tertiary amine compound different from the compound represented by Formula (1), and a quaternary ammonium compound.

[6] The semiconductor treatment liquid according to [3],
in which a mass ratio of a content of the compound represented by Formula (1) to a content of the purine compound is 0.1 to 10.0.

[7] The semiconductor treatment liquid according to [5],
in which a mass ratio of a content of the compound represented by Formula (1) to the total content of the tertiary amine compound different from the compound represented by Formula (1) and the quaternary ammonium compound is 0.005 to 0.15.

[8] The semiconductor treatment liquid according to any one of [1] to [7], further comprising:
an anionic polymer.

[9] The semiconductor treatment liquid according to any one of [1] to [8],
in which the semiconductor treatment liquid is used as a cleaning liquid.

[10] The semiconductor treatment liquid according to any one of [1] to [9],
in which the semiconductor treatment liquid is used for an object to be treated, which has been subjected to a chemical mechanical polishing treatment.

[11] The semiconductor treatment liquid according to any one of [1] to [10],
in which the semiconductor treatment liquid is used for an object to be treated containing at least one metal selected from the group consisting of Cu and Co.

[12] The semiconductor treatment liquid according to any one of [1] to [11],
in which the semiconductor treatment liquid is used for an object to be treated containing at least one metal selected from the group consisting of Cu and Co, which has been subjected to a chemical mechanical polishing treatment.

[13]A treatment method for an object to be treated, comprising:
a step of bringing an object to be treated containing at least one metal selected from the group consisting of Cu and Co, which has been subjected to a chemical mechanical polishing treatment, into contact with the semiconductor treatment liquid according to any one of [1] to [12].

[14]A manufacturing method of an electronic device, comprising:
the treatment method for an object to be treated according to [13].

According to the present invention, it is possible to provide a semiconductor treatment liquid which has excellent anticorrosion properties with a metal and excellent cleanability for organic residues, in a case of being brought into contact with an object to be treated containing a metal, which has been subjected to a chemical mechanical polishing treatment.

In addition, according to the present invention, it is possible to provide a treatment method for an object to be treated, using the treatment liquid, and a manufacturing method of an electronic device.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In addition, in the present specification, in a case where there are two or more components corresponding to a certain component, “content” of such a component means the total content of the two or more components.

In the present specification, “total mass of components in the treatment liquid excluding a solvent” means the total mass of all components contained in the treatment liquid, other than a solvent such as water and an organic solvent.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X—Y—Z” is —COO—, Y may be —CO—O— or —O—CO—. In addition, the above-described compound may be “X—CO—O—Z” or “X—O—CO—Z”.

In the present specification, “ppm” means “parts-per-million (10⁻⁶)”, and “ppb” means “parts-per-billion (10⁻⁹)”.

In the present specification, “weight-average molecular weight” means a weight-average molecular weight in terms of polyethylene glycol measured by gel permeation chromatography (GPC).

### [Semiconductor Treatment Liquid]

Hereinafter, the semiconductor treatment liquid according to the embodiment of the present invention will be described in detail.

The semiconductor treatment liquid (hereinafter, also simply referred to as “treatment liquid”) according to the embodiment of the present invention contains a compound represented by Formula (1) described later (hereinafter, also referred to as “specific compound”), in which a pH of the semiconductor treatment liquid is more than 7.0.

The reason why the treatment liquid having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

The specific compound has no hydroxyl group, and due to a specific structure of the specific compound having an ethylenediamine skeleton including a primary amino group and a secondary amino group or a tertiary amino group, it is difficult to dissolve a metal in the treatment liquid; but performance of dissolving organic residues in the treatment liquid is excellent. It is considered that the treatment liquid contains such a specific compound, and the pH thereof is controlled to a range in which corrosiveness of the metal is low and the solubility of the organic residues is exhibited, so that both the anticorrosion properties with the metal and the cleanability for the organic residue can be achieved.

Hereinafter, the fact that at least one of the anticorrosion properties or the cleanability is more excellent in the semiconductor treatment liquid according to the embodiment of the present invention is also referred to as “effect of the present invention is more excellent”.

### [Specific Compound]

The treatment liquid contains a compound represented by Formula (1) (specific compound).

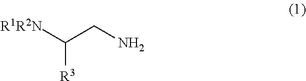

In Formula (1), R¹ to R³ each independently represent a hydrogen atom or an alkyl group which may have a substituent other than a hydroxyl group, where at least one of R¹ or R² represents the alkyl group which may have a substituent other than a hydroxyl group.

At least two selected from R¹ to R³ may be bonded to each other through a single bond or a divalent linking group to form a ring.

The alkyl group represented by R¹ to R³ may be linear, branched, or cyclic, and is preferably linear or branched, and more preferably linear. The number of carbon atoms in the above-described alkyl group is preferably 1 to 15, more preferably 1 to 6, still more preferably 1 to 3, and particularly preferably 1.

Specific examples of the alkyl group represented by R¹ to R³ include a methyl group, an ethyl group, an n-propyl group, an isopropyl group, an n-butyl group, a t-butyl group, an isobutyl group, and an n-hexyl group; and a methyl group, an ethyl group, an n-propyl group, or an isopropyl group is preferable, and a methyl group is more preferable.

Examples of the substituent other than a hydroxyl group, which may be included in the above-described alkyl group, include a halogen atom, an alkoxy group, and an acyl group.

It is also preferable that the above-described alkyl group does not have an amino group (for example, a primary amino group, a secondary amino group, and a tertiary amino group) as the substituent.

In a case where the above-described alkyl group has the substituent, the number of substituents included in the alkyl group is preferably 1 to 3 and more preferably 1.

As R¹ to R³, a hydrogen atom or an alkyl group having 1 to 6 carbon atoms is preferable, a hydrogen atom or a linear alkyl group having 1 to 3 carbon atoms is more preferable, and a hydrogen atom or a methyl group is still more preferable.

At least one of R¹ or R² represents the alkyl group which may have a substituent other than a hydroxyl group. The other of R¹ and R² may be any of the hydrogen atom or the alkyl group which may have a substituent other than a hydroxyl group.

At least two selected from R¹ to R³ may be bonded to each other through a single bond or a divalent linking group to form a ring.

Examples of the above-described divalent linking group include a divalent hydrocarbon group which may have a substituent other than a hydroxyl group, —O—, —S—, —CO—, —NH—, —SO₂—, —NR—, and a group formed by a combination of these groups. R represents an alkyl group.

Examples of the above-described divalent hydrocarbon group include a divalent aliphatic hydrocarbon group such as an alkylene group (preferably having 1 to 10 carbon atoms and more preferably having 1 to 5 carbon atoms), an alkenylene group (preferably having 1 to 10 carbon atoms and more preferably having 1 to 5 carbon atoms), and an alkynylene group (preferably having 1 to 10 carbon atoms and more preferably having 1 to 5 carbon atoms), and a divalent aromatic hydrocarbon ring group such as an arylene group.

Examples of the substituent other than a hydroxyl group, which may be included in the above-described divalent hydrocarbon group, include a halogen atom such as a fluorine atom, a chlorine atom, and a bromine atom, an alkoxy group, an acyl group such as an acetyl group, a propionyl group, and a benzoyl group, a cyano group, and a nitro group; and a halogen atom, an alkoxy group, or an acyl group is preferable.

The above-described divalent aliphatic hydrocarbon group may be linear, branched, or cyclic, and is preferably linear or branched, and more preferably linear.

Among these, as the above-described divalent linking group, a divalent aliphatic hydrocarbon group which may have a substituent other than a hydroxyl group is preferable; an alkylene group which may have a substituent other than a hydroxyl group is more preferable; and an alkylene group having 1 to 5 carbon atoms is still more preferable.

The ring formed by bonding at least two selected from R¹ to R³ may be monocyclic or polycyclic, and is preferably monocyclic.

In addition, the above-described ring is preferably an aliphatic heterocycle.

The above-described ring may include a nitrogen atom to which R¹ and R² specified in the formula are bonded, and may further include a heteroatom. Examples of the above-described heteroatom include an oxygen atom, a sulfur atom, and a nitrogen atom.

The number of heteroatoms in the above-described ring is preferably 1 to 3 and more preferably 1. The above-described number of heteroatoms is the number including the nitrogen atom to which R¹ and R² specified in the formula are bonded.

The number of ring member atoms in the above-described ring is preferably 3 to 12, more preferably 3 to 8, and still more preferably 5 or 6.

Among these, the above-described ring is preferably an aliphatic heterocyclic ring including one nitrogen atom, more preferably a piperidine ring or a pyrrolidine ring, and still more preferably a piperidine ring.

The above-described ring may have a substituent other than a hydroxyl group. Examples of the substituent which may be included in the above-described ring include an alkyl group, an aryl group, an alkoxy group, an acyl group, and a halogen atom; and an alkyl group is preferable.

In a case where at least two selected from R¹ to R³ are bonded to each other through a single bond or a divalent linking group to form a ring, R¹, R², and R³ may be bonded to each other to form a ring or two selected from R¹ to R³ may be bonded to each other to form a ring, but it is preferable that R¹ and R² or R¹ and R³ are bonded to each other to form a ring.

In a case where R¹ and R² are bonded to each other through a single bond or a divalent linking group, a bonding position formed by removing one hydrogen atom from the alkyl group represented by R¹ and a bonding position formed by removing one hydrogen atom from the alkyl group represented by R² are bonded to each other through a single bond or a divalent linking group. In addition, in a case where R¹ and R³ are bonded to each other through a single bond or a divalent linking group, a bonding position formed by removing one hydrogen atom from the alkyl group represented by R¹ and a bonding position formed by removing one hydrogen atom from the alkyl group represented by R³ are bonded to each other through a single bond or a divalent linking group.

A compound in which R¹ and R² are bonded to each other through a single bond or a divalent linking group to form a ring is preferably a compound represented by Formula (1-1). In addition, a compound in which R¹ and R³ are bonded to each other through a single bond or a divalent linking group to form a ring is preferably a compound represented by Formula (1-2).

Among these, the compound in which at least two selected from R¹ to R³ are bonded to each other through a single bond or a divalent linking group to form a ring is preferably the compound represented by Formula (1-2).

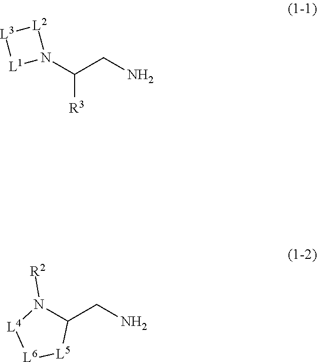

In Formula (1-1), L¹ and L² each independently represent an alkylene group which may have a substituent other than a hydroxyl group.

The above-described alkylene group may be linear, branched, or cyclic, and is preferably linear or branched, and more preferably linear. The number of carbon atoms in the above-described alkylene group is preferably 1 to 10, more preferably 1 to 5, and still more preferably 1 to 3.

Examples of the substituent other than a hydroxyl group, which may be included in the above-described alkylene group, include the substituents which may be included in R¹ and R², and a suitable aspect thereof is also the same.

In Formula (1-1), L³ represents a single bond or a divalent linking group. Examples of the divalent linking group represented by L³ include the groups exemplified as the divalent linking group in a case where at least two selected from R¹ to R³ are bonded to each other through a single bond or a divalent linking group to form a ring.

As L³, a single bond or an alkylene group is preferable, and a single bond is more preferable.

In Formula (1-1), the definition and the suitable aspect of R³ are the same as the definition and the suitable aspect of R³ in Formula (1). Among these, R³ is preferably a hydrogen atom.

Examples of the compound represented by Formula (1-1) include 1-(2-aminoethyl)piperidine and 1-(2-aminoethyl)pyrrolidine.

In Formula (1-2), L⁴ and L⁵ each independently represent an alkylene group which may have a substituent other than a hydroxyl group.

The above-described alkylene group may be linear, branched, or cyclic, and is preferably linear or branched, and more preferably linear. The number of carbon atoms in the above-described alkylene group is preferably 1 to 10, more preferably 1 to 5, and still more preferably 1 to 3.

Examples of the substituent which may be included in the above-described alkylene group include the substituents which may be included in R¹ and R³, and a suitable aspect thereof is also the same.

In Formula (1-2), L⁶ represents a single bond or a divalent linking group. Examples of the divalent linking group represented by L⁶ include the groups exemplified as the divalent linking group in a case where at least two selected from R¹ to R³ are bonded to each other through a single bond or a divalent linking group to form a ring.

As L⁶, a single bond or a divalent alkylene group is preferable, and a single bond is more preferable.

In Formula (1-2), the definition and the suitable aspect of R² are the same as the definition and the suitable aspect of R² in Formula (1). Among these, R² is preferably a hydrogen atom.

Examples of the compound represented by Formula (1-2) include 2-aminomethylpiperidine, 2-aminomethyl-1-methylpiperidine, 2-aminomethyl-1-ethylpiperidine, and 2-aminomethyl-1-ethylpyrrolidine; and 2-aminomethylpiperidine is preferable.

Examples of the compound represented by Formula (1), in which at least two selected from R¹ to R³ are bonded to each other through a single bond or a divalent linking group to form a ring, include N-methylethylenediamine, N-ethylethylenediamine, N-butylethylenediamine, N-isopropylethylenediamine, N,N-dimethylethylenediamine, N-ethyl-N-methylethylenediamine, N,N-diethylethylenediamine, N,N-diisopropylethylenediamine, and N,N-dibutylethylenediamine; and N-methylethylenediamine, N-ethylethylenediamine, or N,N-dimethylethylenediamine is preferable, and N-methylethylenediamine or N,N-dimethylethylenediamine is more preferable.

Among these, as the specific compound, 2-aminomethylpiperidine, N-ethylethylenediamine, N-methylethylenediamine, or N,N-dimethylethylenediamine is preferable; 2-aminomethylpiperidine, N-methylethylenediamine, or N,N-dimethylethylenediamine is more preferable; and 2-aminomethylpiperidine is still more preferable.

The specific compound may be used alone, or two or more types thereof may be used in combination.

From the viewpoint that the effect of the present invention is more excellent, a content of the specific compound is preferably 0.0001% to 5.0% by mass and more preferably 0.0003% to 1.0% by mass with respect to the total mass of the treatment liquid.

From the viewpoint that the cleanability is more excellent, the content of the specific compound is preferably 0.05% by mass or more, more preferably 0.1% by mass or more, and still more preferably 0.7% by mass or more with respect to the total mass of components in the treatment liquid excluding a solvent. From the viewpoint that the anticorrosion properties are more excellent, the upper limit thereof is preferably 30.0% by mass or less, more preferably 13.0% by mass or less, and still more preferably 3.5% by mass or less.

The treatment liquid may contain a component other than the specific compound.

Hereinafter, other components will be described in detail.

### [Purine Compound]

From the viewpoint that the anticorrosion properties are more excellent, the treatment liquid preferably contains at least one purine compound selected from the group consisting of purine and a purine derivative.

From the viewpoint that the effect of the present invention is more excellent, the purine compound preferably includes at least one compound selected from the group consisting of compounds represented by Formulae (C1) to (C4); more preferably includes at least one compound selected from the group consisting of a compound represented by Formula (C1) and a compound represented by Formula (C2); and still more preferably includes at least one compound selected from the group consisting of a compound represented by Formula (C5) and a compound represented by Formula (C7).

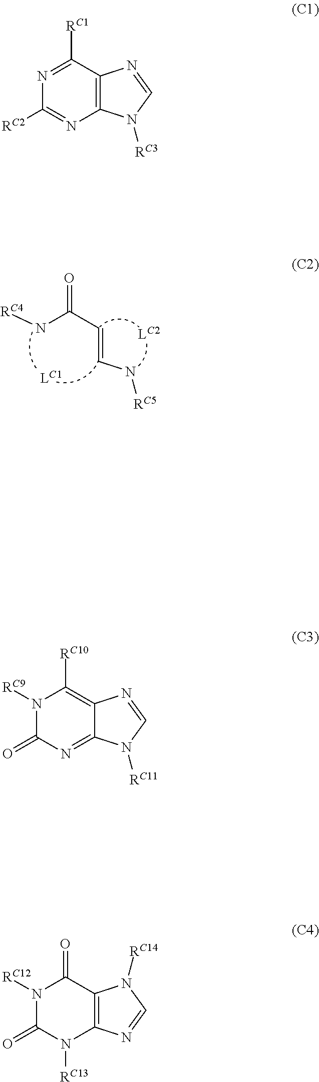

In Formula (C1), R^{C1} to R^{C3} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

The above-described alkyl group may be linear, branched, or cyclic. The number of carbon atoms in the above-described alkyl group is preferably 1 to 10, more preferably 1 to 5, and still more preferably 1 to 3.

Examples of the above-described sugar group include a group obtained by removing one hydroxyl group from a sugar selected from the group consisting of a monosaccharide, a disaccharide, and a polysaccharide; and a group obtained by removing one hydroxyl group from a monosaccharide is preferable.

Examples of the monosaccharide include a pentose such as ribose, deoxyribose, arabinose, or xylose, a triose, a tetrose, a hexose, and a heptose; and a pentose is preferable, ribose, deoxyribose, arabinose, or xylose is more preferable, and ribose or deoxyribose is still more preferable.

Examples of the disaccharides include sucrose, lactose, maltose, trehalose, turanose, and cellobiose.

Examples of the polysaccharides include glycogen, starch, and cellulose.

The above-described saccharides may be chain-like or cyclic, and are preferably cyclic.

Examples of the above-described cyclic saccharides include a furanose ring and a pyranose ring.

The polyoxyalkylene group-containing group which may have a substituent means a group containing, as a part of the group, a polyoxyalkylene group, which may have a substituent.

Examples of the polyoxyalkylene group constituting the polyoxyalkylene group-containing group include a polyoxyethylene group, a polyoxypropylene group, and a polyoxybutylene group; and a polyoxyethylene group is preferable.

Examples of the substituent included in the alkyl group, amino group, sugar group, and polyoxyalkylene group-containing group described above include a hydrocarbon group such as an alkyl group which may have a substituent, an aryl group, and a benzyl group; a halogen atom such as a fluorine atom, a chlorine atom, and a bromine atom; an alkoxy group; a hydroxyl group; an alkoxycarbonyl group such as a methoxycarbonyl group and an ethoxycarbonyl group; an acyl group such as an acetyl group, a propionyl group, and a benzoyl group; a cyano group; and a nitro group.

Examples of the substituent which may be included in the above-described alkyl group which may have a substituent include the groups exemplified as the above-described substituent, and more specific examples thereof include an aryl group and a heteroaryl group.

R^{C1} is preferably a hydrogen atom or an amino group which may have a substituent, and more preferably an amino group which may have a substituent.

Another suitable aspect of R^{C1} is preferably an alkyl group which may have a substituent, a thiol group, a hydroxyl group, a halogen atom, a sugar group which may have a substituent, or a polyoxyalkylene group-containing group which may have a substituent.

R^{C2} is preferably a hydrogen atom or an alkyl group which may have a substituent, and more preferably a hydrogen atom.

R^{C3} is preferably a hydrogen atom, an alkyl group which may have a substituent, or a sugar group which may have a substituent, and more preferably a hydrogen atom or a sugar group which may have a substituent.

In Formula (C2), L^{C1} represents —CR^{C6}═N— or —C(═O)—NR^{C7}—. L^{C2} represents —N═CH— or —NR^{C8}—C(═O)—. R^{C4} to R^{C8} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C4} to R^{C8} include the above-described aspect of each group represented by R^{C1} to R^{C3} in Formula (C1).

R^{C4} and R^{C5} are preferably a hydrogen atom or an alkyl group which may have a substituent, and more preferably a hydrogen atom.

R^{C6} is preferably a hydrogen atom, an alkyl group which may have a substituent, or an amino group which may have a substituent, and more preferably a hydrogen atom.

L^{C1} is preferably —C(═O)—NR^{C7}—.

R^{C7} is preferably a hydrogen atom or an alkyl group which may have a substituent, and more preferably a hydrogen atom.

L^{C2} is preferably —N═CH—.

R^{C8} is preferably a hydrogen atom or an alkyl group which may have a substituent, and more preferably a hydrogen atom.

In Formula (C3), R^{C9} to R^{C11} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C9} to R^{C11} include the above-described groups represented by R^{C1} to R^{C3} in Formula (C1).

R^{C9} is preferably a hydrogen atom or an alkyl group which may have a substituent, and more preferably a hydrogen atom.

R^{C10} is preferably a hydrogen atom, an alkyl group which may have a substituent, or an amino group which may have a substituent, more preferably a hydrogen atom or an amino group which may have a substituent, and still more preferably an amino group which may have a substituent.

R^{C11} is preferably a hydrogen atom or an alkyl group which may have a substituent, and more preferably a hydrogen atom.

In Formula (C4), R^{C2} to R^{C14} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C12} to R^{C14} include the above-described groups represented by R^{C1} to R^{C3} in Formula (C1).

R^{C12} is preferably a hydrogen atom or an alkyl group which may have a substituent, and more preferably an alkyl group which may have a substituent.

Another suitable aspect of R^{C12} is preferably an alkyl group which may have a substituent, an amino group which may have a substituent, a thiol group, a hydroxyl group, a halogen atom, a sugar group which may have a substituent, or a polyoxyalkylene group-containing group which may have a substituent.

R^{C13} is preferably a hydrogen atom or an alkyl group which may have a substituent, and more preferably an alkyl group which may have a substituent.

R^{C14} is preferably a hydrogen atom or an alkyl group which may have a substituent.

As the compound represented by Formula (C1), a compound represented by Formula (C5) is preferable.

As the compound represented by Formula (C2), a compound represented by any one of Formula (C6) to Formula (C8) is preferable, and a compound represented by Formula (C7) is more preferable.

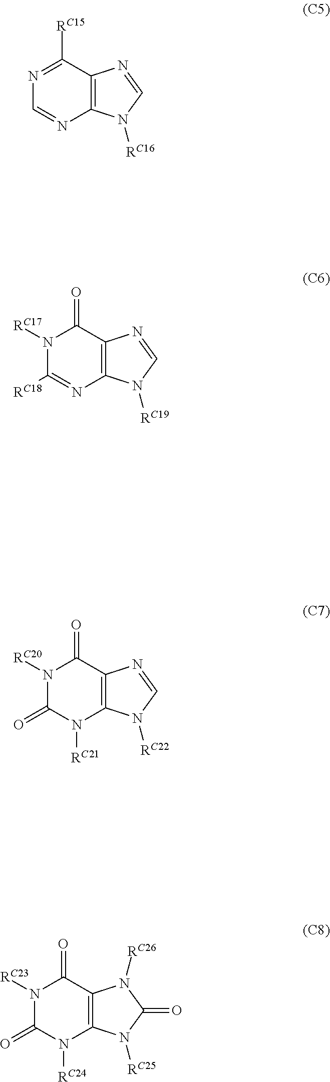

In Formula (C5), R^{C15} and R^{C16} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C15} and R^{C16} include the above-described groups represented by R^{C1} to R^{C3} in Formula (C1).

R^{C15} is preferably a hydrogen atom, an alkyl group which may have a substituent, or an amino group which may have a substituent, and more preferably an amino group which may have a substituent.

R^{C16} is preferably a hydrogen atom, an alkyl group which may have a substituent, or a sugar group which may have a substituent, more preferably a hydrogen atom or a sugar group which may have a substituent, and still more preferably a hydrogen atom.

In Formula (C6), R^{C17} to R^{C19} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C17} to R^{C19} include the above-described groups represented by R^{C1} to R^{C3} in Formula (C1).

R^{C17} to R^{C19} are preferably a hydrogen atom or an alkyl group which may have a substituent, and more preferably a hydrogen atom.

In Formula (C7), R^{C20} to R^{C22} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C20} to R^{C22} include the above-described groups represented by R^{C1} to R^{C3} in Formula (C1).

R^{C20} to R^{C22} are preferably a hydrogen atom or an alkyl group which may have a substituent, and more preferably a hydrogen atom.

In Formula (C8), R^{C23} to R^{C26} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

Examples of an aspect of each group represented by R^{C23} to R^{C26} include the above-described groups represented by R^{C1} to R^{C3} in Formula (C1).

R^{C23} to R^{C26} are preferably a hydrogen atom or an alkyl group which may have a substituent, and more preferably a hydrogen atom.

Examples of the purine compound include purine, adenine, xanthine, 6-methylaminopurine (methyladenine), kinetin, 6-benzyladenine, adenosine, hypoxanthine, guanine, theobromine, caffeine, uric acid, isoguanine, enprofylline, theophylline, xanthosine, 7-methylxanthosine, 7-methylxanthine, eritadenine, dimethyladenine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl)xanthine, 1-butyl-3,7-dimethylxanthine, 3,7-dimethyl-1-propylxanthine, mercaptopurine, 2-aminopurine, nelarabine, vidarabine, 2,6-dichloropurine, acyclovir, N6-benzoyladenosine, trans-zeatin, entecavir, valacyclovir, abacavir, 2′-deoxyguanosine, disodium inosinate, ganciclovir, guanosine-5′-monophosphate disodium salt, O-cyclohexylmethylguanine, N2-isobutyryl-2′-deoxyguanosine, β-nicotinamide adenine dinucleotide phosphate, 6-chloro-9-(tetrahydropyran-2-yl)purine, clofarabine, 7-(2,3-dihydroxypropyl)theophylline, 6-mercaptopurine, proxyphylline, 2,6-diaminopurine, 2′,3′-dideoxyinosine, theophylline-7-acetic acid, 2-chloroadenine, 2-amino-6-chloropurine, 8-bromo-3-methylxanthine, 2-fluoroadenine, penciclovir, 9-(2-hydroxyethyl)adenine, 7-(2-chloroethyl)theophylline, 2-amino-6-iodopurine, 2-thioxanthine, 2-amino-6-methoxypurine, N-acetylguanine, adefovir dipivoxil, 8-chlorotheophylline, and 6-methoxypurine.

Among these, the purine compound preferably includes at least one selected from the group consisting of purine, adenine, xanthine, methyladenine, kinetin, 6-benzyladenine, adenosine, hypoxanthine, theobromine, caffeine, uric acid, dimethyladenine, enprofylline, xanthosine, 7-methylxanthosine, 7-methylxanthine, theophylline, eritadenine, paraxanthine, 3-methylxanthine, 1,7-dimethylxanthine, and 1-methylxanthine; more preferably includes at least one selected from the group consisting of adenine, xanthine, methyladenine, kinetin, 6-benzyladenine, adenosine, and hypoxanthine; and still more preferably includes at least one selected from the group consisting of adenine, xanthine, methyladenine, kinetin, 6-benzyladenine, and adenosine.

The purine compound may be used alone or in combination of two or more thereof.

From the viewpoint that the effect of the present invention is more excellent, a content of the purine compound is preferably 0.0001% to 1.0% by mass and more preferably 0.0002% to 0.1% by mass with respect to the total mass of the treatment liquid.

From the viewpoint that the anticorrosion properties are more excellent, the content of the purine compound is preferably 0.05% by mass or more, more preferably 0.1% by mass or more, and still more preferably 0.5% by mass or more with respect to the total mass of components in the treatment liquid excluding a solvent. From the viewpoint that the cleanability is more excellent, the upper limit thereof is preferably 15.0% by mass or less, more preferably 10.0% by mass or less, and still more preferably 5.0% by mass or less.

From the viewpoint that the cleanability is more excellent, a mass ratio of the content of the specific compound to the content of the purine compound is preferably 0.01 or more, more preferably 0.1 or more, and still more preferably 0.5 or more. From the viewpoint that the anticorrosion properties are more excellent, the upper limit thereof is preferably 15.0 or less, more preferably 10.0 or less, and still more preferably 5.0 or less.

[Tertiary Amine Compound Different from Specific Compound, and Quaternary Ammonium Compound]

From the viewpoint that the pH can be appropriately controlled and the effect of the present invention is more excellent, it is also preferable that the treatment liquid contains at least one compound selected from the group consisting of a tertiary amine compound different from the specific compound, and a quaternary ammonium compound. Hereinafter, the tertiary amine compound different from the specific compound is also referred to as “tertiary amine compound X”.

It is noted that both the tertiary amine compound X and the quaternary ammonium compound are compounds different from the specific compound and the purine compound described above.

The treatment liquid may contain two or more kinds of the at least one compound selected from the group consisting of the tertiary amine compound X and the quaternary ammonium compound. In a case where the treatment liquid contains two or more kinds of the at least one compound selected from the group consisting of the tertiary amine compound X and the quaternary ammonium compound, a combination thereof is not particularly limited; and the treatment liquid may contain two or more kinds of any of the tertiary amine compound X or the quaternary ammonium compound, or may contain one or more kinds of the tertiary amine compound X and one or more kinds of the quaternary ammonium compound.

The total content of the tertiary amine compound X and the quaternary ammonium compound is preferably 0.005% to 15.0% by mass, more preferably 0.010% to 10.0% by mass, and still more preferably 0.020% to 10.0% by mass with respect to the total mass of the treatment liquid.

The total content of the tertiary amine compound X and the quaternary ammonium compound is preferably 50.0% to 99.9% by mass, more preferably 75.0% to 99.5% by mass, and still more preferably 85.0% to 99.0% by mass with respect to the total mass of components in the treatment liquid excluding a solvent.

From the viewpoint that the cleanability is more excellent, a mass ratio of the content of the specific compound to the total content of the tertiary amine compound X and the quaternary ammonium compound is preferably 0.001 or more, more preferably 0.005 or more, and still more preferably 0.007 or more. From the viewpoint that the anticorrosion properties are more excellent, the upper limit thereof is preferably 1.0 or less, more preferably 0.15 or less, and still more preferably 0.1 or less.

A mass ratio of the total content of the tertiary amine compound X and the quaternary ammonium compound to the content of the purine compound is preferably 1.0 to 400.0, more preferably 10.0 to 300.0, and still more preferably 30.0 to 200.0.

Hereinafter, the tertiary amine compound X and the quaternary ammonium compound, which may be contained in the treatment liquid, will be described in detail.

### <Tertiary Amine Compound X>

The tertiary amine compound X is a compound different from the specific compound and having at least one tertiary amino group in the molecule.

The tertiary amine compound X may have two or more tertiary amino groups in the molecule.

The tertiary amine compound X may have a substituent different from the tertiary amino group, and examples of the substituent include a halogen atom such as a fluorine atom, a chlorine atom, and a bromine atom, an alkyl group, an alkoxy group, a hydroxyl group; an alkoxycarbonyl group such as a methoxycarbonyl group and an ethoxycarbonyl group, an acyl group such as an acetyl group, a propionyl group, and a benzoyl group, an amino group such as a primary amino group and a secondary amino group, a cyano group, a nitro group, a thiol group, and a dioxiranyl group; and an amino group or a hydroxyl group is preferable, and a hydroxyl group is more preferable.

Examples of the tertiary amine compound X include an amino alcohol having a hydroxyl group. Examples of the amino alcohol include 2-dimethylamino-2-methyl-1-propanol (DMAMP), N-methyldiethanolamine (MDEA), 2-(dimethylamino)ethanol (DMAE), 2-(diethylamino)ethanol, N-ethyldiethanolamine (EDEA), 2-(dibutylamino)ethanol, 2-[2-(dimethylamino)ethoxy]ethanol, 2-[2-(diethylamino)ethoxy]ethanol, triethanolamine, and N-butyldiethanolamine (BDEA).

In addition, examples of the tertiary amine compound X also include alkylamines such as trimethylamine and triethylamine; alkylenediamines such as 1-(2-hydroxyethyl)piperazine (HEP), 1,4-diazabicyclo[2.2.2]octane (DABCO), 1-methylpiperazine, 1,4-dimethylpiperazine, 1,3-bis(dimethylamino)butane, and N,N,N′,N′-tetramethyl-1,3-propanediamine; and polyalkylpolyamines such as N,N,N′,N″,N″-pentamethyldiethylenetriamine (PMDETA).

As the tertiary amine compound X, an amino alcohol, an alkylenediamine, or a polyalkylpolyamine is preferable. Among these, DMAMP, PMDETA, DMAE, or EDEA is preferable, and DMAMP or PMDETA is more preferable.

The tertiary amine compound X may be used alone, or two or more types thereof may be used in combination.

A content of the tertiary amine compound X is preferably 0.001% to 15.0% by mass, more preferably 0.002% to 10.0% by mass, and still more preferably 0.01% to 5.0% by mass with respect to the total mass of the treatment liquid.

The content of the tertiary amine compound X is preferably 10.0% to 99.9% by mass, more preferably 20.0% to 99.0% by mass, and still more preferably 40.0% to 60.0% by mass with respect to the total mass of components in the treatment liquid excluding a solvent.

A mass ratio of the content of the specific compound to the content of the tertiary amine compound X is preferably 0.001 to 1.5, more preferably 0.005 to 0.1, and still more preferably 0.01 to 0.05.

### <Quaternary Ammonium Compound>

The quaternary ammonium compound is preferably a compound having a quaternary ammonium cation in which a nitrogen atom is substituted with four hydrocarbon groups (preferably, alkyl groups). In addition, the quaternary ammonium compound may be a compound having a quaternary ammonium cation in which a nitrogen atom in a pyridine ring is bonded to a substituent (a hydrocarbon group such as an alkyl group and an aryl group), for example, an alkyl pyridinium.

Examples of the quaternary ammonium compound include a quaternary ammonium hydroxide, a quaternary ammonium acetate, and a quaternary ammonium carbonate.

The quaternary ammonium compound is preferably a compound represented by Formula (A).

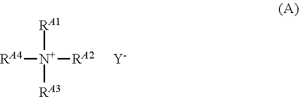

In Formula (A), R^{A1} to R^{A4} each independently represent a hydrocarbon group which may have a substituent.

Examples of the substituent which may be included in the above-described hydrocarbon group include a halogen atom such as a fluorine atom, a chlorine atom, and a bromine atom, an alkyl group, an alkoxy group, a hydroxyl group, an alkoxycarbonyl group such as a methoxycarbonyl group and an ethoxycarbonyl group, an acyl group such as an acetyl group, a propionyl group, and benzoyl group, a cyano group, a nitro group, a thiol group, and a dioxiranyl group; and a hydroxyl group is preferable.

In a case where the above-described hydrocarbon group has a substituent, the number of substituents is preferably 1 to 5, more preferably 1 to 3, and still more preferably 1.

The number of carbon atoms in the above-described hydrocarbon group is preferably 1 to 20, more preferably 1 to 10, still more preferably 1 to 5, and particularly preferably 1 to 3.

Examples of the above-described hydrocarbon group include an alkyl group, an alkenyl group, an alkynyl group, an aryl group, and a group obtained by combining these groups.

The above-described alkyl group may be linear, branched, or cyclic. The number of carbon atoms in the above-described alkyl group is preferably 1 to 20, more preferably 1 to 10, still more preferably 1 to 5, and particularly preferably 1 to 3.

Examples of the above-described alkyl group include a methyl group, an ethyl group, an n-propyl group, an isopropyl group, an n-butyl group, and a t-butyl group; and a methyl group, an ethyl group, an n-propyl group, or an isopropyl group is preferable, and a methyl group or an ethyl group is more preferable.

The alkenyl group and alkynyl group described above may be linear, branched, or cyclic. The number of carbon atoms in the alkenyl group and alkynyl group described above is preferably 2 to 20, more preferably 2 to 10, and still more preferably 2 to 5.

Examples of the alkenyl group and alkynyl group described above include a vinyl group, an allyl group, an ethynyl group, and a propargyl group.

The above-described aryl group may be monocyclic or polycyclic. The number of carbon atoms in the above-described aryl group is preferably 6 to 20, more preferably 6 to 10, and still more preferably 6 to 8.

Examples of the above-described aryl group include a benzyl group, a phenyl group, a naphthyl group, an anthryl group, a phenanthryl group, an indenyl group, an acenaphthenyl group, a fluorenyl group, and a pyrenyl group; and a benzyl group or a phenyl group is preferable, and a phenyl group is more preferable.

As the group represented by R^{A1} to R^{A4}, the alkyl group or the aryl group is preferable, the alkyl group is more preferable, and a linear or branched alkyl group having 1 to 5 carbon atoms is still more preferable.

It is also preferable that three or more of R^{A1} to R^{A4} represent the same group. For example, it is preferable that R^{A1} to R^{A3} represent a methyl group and R^{A4} represents an ethyl group, and it is also preferable that all of R^{A1} to R^{A4} represent a methyl group.

The total number of carbon atoms in the groups represented by R^{A1} to R^{A4} is not particularly limited, but is 4 or more, preferably 4 to 30, more preferably 4 to 25, still more preferably 4 to 15, and particularly preferably 5 to 10.

Y⁻ represents an anion.

Examples of the anion include acid anions such as a carboxylate ion, a phosphate ion, a phosphonate ion, and a nitrate ion, and a hydroxide ion; and a hydroxide ion is preferable.

Examples of the quaternary ammonium compound include ethyltrimethylammonium hydroxide (ETMAH), tris(2-hydroxyethyl)methylammonium hydroxide (THEMAH), dimethylbis(2-hydroxyethyl)ammonium hydroxide, tetramethylammonium hydroxide (TMAH), trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-hydroxyethyl)dimethylammonium hydroxide, tri(2-hydroxyethyl)methylammonium hydroxide, tetra(2-hydroxyethyl)ammonium hydroxide, benzyltrimethylammonium hydroxide (BTMAH), and cetyltrimethylammonium hydroxide; and ETMAH, MTEAH, TEAH, or TBAH is preferable, and ETMAH is more preferable.

The quaternary ammonium compound may be used alone, or two or more types thereof may be used in combination.

A content of the quaternary ammonium compound is preferably 0.001% to 10.0% by mass, more preferably 0.005% to 8.0% by mass, and still more preferably 0.01% to 3.0% by mass with respect to the total mass of the treatment liquid.

The content of the quaternary ammonium compound is preferably 30.0% to 99.0% by mass, and more preferably 40.0% to 95.0% by mass with respect to the total mass of components in the treatment liquid excluding a solvent.

A mass ratio of the content of the specific compound to the content of the quaternary ammonium compound is preferably 0.001 to 0.5, more preferably 0.015 to 0.1, and still more preferably 0.02 to 0.05.

### [Water]

It is preferable that the treatment liquid contains water.

The type of water used in the treatment liquid may be any type of water as long as it does not adversely affect the semiconductor substrate; and distilled water, deionized (DI) water, or pure water (ultrapure water) can be used. The pure water (ultrapure water) is preferable from the viewpoint that it contains almost no impurities and has less influence on a semiconductor substrate in a step of manufacturing the semiconductor substrate.

A content of water may be a remainder of components which can be contained in the treatment liquid.

The content of the water is preferably 30.0% by mass or more, more preferably 60.0% by mass or more, still more preferably 80.0% by mass or more, and particularly preferably 90.0% by mass or more with respect to the total mass of the treatment liquid. The upper limit thereof is preferably 99.995% by mass or less, more preferably 99.99% by mass or less, and still more preferably 99.98% by mass or less with respect to the total mass of the treatment liquid.

### [Other Components]

The treatment liquid may contain, as other components in addition to the above-described components, at least one component selected from the group consisting of other amine compounds, a pH adjuster, an organic acid, a surfactant, an organic solvent, a polymer, a polyhydroxy compound having a molecular weight of 500 or more, and an oxidant.

Hereinafter, other components will be described in detail.

### <Other Amine Compounds>

The treatment liquid may contain other amine compounds different from the specific compound, the purine compound, the tertiary amine compound X, and the quaternary ammonium compound described above.

Examples of the other amine compounds include a primary amine compound and a secondary amine compound different from the specific compound. The primary amine compound and the secondary amine compound are each a compound having a primary amino group (—NH₂) or a secondary amino group (>NH) in the molecule. Furthermore, in a case where the compound has amino groups of different classes, it is classified into the highest amine compound.

The number of primary amino groups and secondary amino groups in the other amine compounds is not particularly limited, but is preferably 1 to 6.

Examples of the primary amine compound include monoethanolamine (MEA), uracil, 2-amino-2-methyl-1-propanol (AMP), 3-amino-1-propanol, 1-amino-2-propanol, tris(hydroxymethyl)aminomethane, diethyleneglycolamine (DEGA), 2-(aminoethoxy)ethanol (AEE), ethylenediamine, 1,3-propanediamine (PDA), 1,2-propanediamine, 1,3-butanediamine, and 1,4-butanediamine.

Examples of the secondary amine compound different from the specific compound include N-methyl-2-amino-2-methyl-propanol (MAMP), 2-(2-aminoethylamino)ethanol (AAE), N,N′-bis(2-hydroxyethyl)ethylenediamine, N-methylethanolamine, 2-(ethylamino)ethanol, 2-[(hydroxymethyl)amino]ethanol, 2-(propylamino)ethanol, diethanolamine, N-butylethanolamine, N-cyclohexylethanolamine, piperazine, and 2,5-dimethylpiperazine.

The other amine compounds may be used alone, or two or more types thereof may be used in combination.

A content of the other amine compounds is preferably 0.0001% to 5.00% by mass, more preferably 0.0005% to 1.00% by mass, and still more preferably 0.001% to 0.10% by mass with respect to the total mass of the treatment liquid.

The content of the other amine compounds is preferably 0.01% to 30.0% by mass, more preferably 0.1% to 10.0% by mass, and still more preferably 0.5% to 5.0% by mass with respect to the total mass of components in the treatment liquid excluding a solvent.

### <pH Adjuster>

The treatment liquid may contain a pH adjuster to adjust and maintain the pH of the treatment liquid.

The pH adjuster is a basic compound or an acidic compound, which is different from the above-described compounds which can be contained in the treatment liquid (the specific compound, the purine compound, the quaternary ammonium compound, the tertiary amine compound, and the other amine compounds). However, it is permissible to adjust the pH of the treatment liquid by adjusting the addition amount of each of the above-described components.

The basic compound is a compound which exhibits basicity (pH of more than 7.0) in an aqueous solution, and examples thereof include a basic inorganic compound.

Examples of the basic inorganic compound include alkali metal hydroxides such as sodium hydroxide and potassium hydroxide, and alkaline earth metal hydroxides.

The acidic compound is a compound which exhibits acidity (a pH of less than 7.0) in an aqueous solution.

Examples of the acidic compound include an acidic inorganic compound.

Examples of the acidic inorganic compound include hydrochloric acid, sulfuric acid, nitric acid, nitrous acid, sulfurous acid, phosphoric acid, boric acid, and hexafluorophosphoric acid.

As the acidic compound as the pH adjuster, a salt of the acidic compound may be used as long as it is an acid or an acid ion (anion) in an aqueous solution.

The pH adjuster may be used alone, or two or more types thereof may be used in combination.

A content of the pH adjuster can be selected depending on the type and amount of other components and the target pH of the treatment liquid. For example, the content of the pH adjuster is preferably 0.001% to 5% by mass, more preferably 0.005% to 3% by mass, and still more preferably 0.01% to 1% by mass with respect to the total mass of the treatment liquid.

### <Organic Acid>

The organic acid is an organic compound having an acid group, which is different from each of the above-described components.

Examples of the organic acid include a carboxylic acid, a phosphonic acid, and a sulfonic acid.

The organic acid may be in a form of a salt. Examples of the above-described salt include an inorganic salt.

Examples of the carboxylic acid include a polycarboxylic acid and a hydroxycarboxylic acid.

Examples of the polycarboxylic acid include citric acid, malonic acid, maleic acid, succinic acid, malic acid, tartaric acid, oxalic acid, glutaric acid, adipic acid, pimelic acid, and sebacic acid.

Examples of the hydroxycarboxylic acid include gluconic acid, heptonic acid, glycolic acid, and lactic acid.

As the phosphonic acid, compounds described in paragraphs [0026] to [0036] of WO2018/020878A and compounds ((co)polymers) described in paragraphs [0031] to [0046] of WO2018/030006A can be used, the contents of which are incorporated herein by reference.

Examples of the sulfonic acid include p-toluenesulfonic acid, naphthalenesulfonic acid, camphor sulfonic acid, benzenesulfonic acid, methanesulfonic acid, ethanesulfonic acid, methanedisulfonic acid, 1,2-ethanesulfonic acid, and 1,3-benzenedisulfonic acid.

The organic acid may be used alone, or two or more types thereof may be used in combination.

A content of the organic acid is preferably 0.0001% to 5.00% by mass, more preferably 0.0005% to 1.00% by mass, and still more preferably 0.001% to 0.10% by mass with respect to the total mass of the treatment liquid.

The content of the organic acid is preferably 0.1% to 50.0% by mass, more preferably 0.5% to 30.0% by mass, and still more preferably 1.0% to 10.0% by mass with respect to the total mass of components in the treatment liquid excluding a solvent.

### <Surfactant>

The surfactant is not particularly limited as long as it is a compound having a hydrophilic group and a hydrophobic group (lipophilic group) in one molecule; and examples thereof include a nonionic surfactant and an anionic surfactant.

In many cases, the surfactant has at least one hydrophobic group selected from the group consisting of an aliphatic hydrocarbon group, an aromatic hydrocarbon group, and a group obtained by combining these groups.

The number of carbon atoms in the surfactant is preferably 16 to 100.

Examples of the nonionic surfactant include an ester-type nonionic surfactant, an ether-type nonionic surfactant, and an ester-ether-type nonionic surfactant; and an ether-type nonionic surfactant is preferable.

As the nonionic surfactant, for example, compounds exemplified in paragraph [0126] of WO2022/044893A can also be used, the contents of which are incorporated herein by reference.

Examples of the anionic surfactant include a phosphoric acid ester-based surfactant having a phosphoric acid ester group, a sulfonic acid-based surfactant having a sulfo group, a phosphonic acid-based surfactant having a phosphonic acid group, a sulfuric acid ester-based surfactant having a sulfuric acid ester group, and a carboxylic acid-based surfactant having a carboxy group.

As the anionic surfactant, for example, compounds exemplified in paragraphs [0116] to [0123] of WO2022/044893A can also be used, the contents of which are incorporated herein by reference.

The surfactant may be used alone, or two or more types thereof may be used in combination.

From the viewpoint of excellent performance of the treatment liquid, a content of the surfactant is preferably 0.0001% to 5.00% by mass, more preferably 0.0005% to 1.00% by mass, and still more preferably 0.001% to 0.10% by mass with respect to the total mass of the treatment liquid.

From the viewpoint of excellent performance of the treatment liquid, the content of the surfactant is preferably 0.1% to 50.0% by mass, more preferably 0.5% to 30.0% by mass, and still more preferably 1.0% to 10.0% by mass with respect to the total mass of components in the treatment liquid excluding a solvent.

### <Organic Solvent>

Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

As the organic solvent, for example, compounds exemplified in paragraphs [0135] to [0140] of WO2022/044893A can be used, the contents of which are incorporated herein by reference.

### <Polymer>

Examples of the polymer include a water-soluble polymer.

The “water-soluble polymer” means a compound having two or more constitutional units linked in a linear or mesh form through a covalent bond, in which a mass of the polymer dissolved in 100 g of water at 20° C. is 0.1 g or more.

As the polymer, water-soluble polymers described in paragraphs [0043] to [0047] of JP2016-171294A can be used, the contents of which are incorporated herein by reference.

Among these, an anionic polymer is preferable as the water-soluble polymer.

The anionic polymer is a polymer including a repeating unit having an anionic functional group which exhibits anionic property in a case of being dissolved in water.

Examples of the above-described anionic functional group include an acid group and a salt thereof. Specific examples of the acid group include a carboxy group, a sulfonic acid group, a phosphonic acid group, and a phenolic hydroxyl group; and a carboxy group or a sulfonic acid group is preferable.

The anionic functional group included in the above-described anionic polymer may be one kind or two or more kinds. In addition, the anionic polymer may be any of a homopolymer or a copolymer.

The above-described anionic polymer preferably has at least one repeating unit selected from the group consisting of a repeating unit derived from acrylic acid and a repeating unit derived from maleic acid.

Specific examples of the above-described anionic polymer include polyacrylic acid, polymaleic acid, an acrylic acid-maleic acid copolymer, a styrene-maleic acid copolymer, an acrylic acid-sulfonic acid-based monomer copolymer, polystyrene sulfonic acid, polyvinyl sulfonic acid, and ammonium polyacrylate.

A weight-average molecular weight (Mw) of the above-described polymer is preferably 500 to 80,000, more preferably 1,000 to 30,000, and still more preferably 2,000 to 20,000.

The above-described polymer may be used alone, or two or more types thereof may be used in combination.

A content of the above-described polymer is preferably 0.0001% to 5.0% by mass and more preferably 0.0005% to 1.0% by mass with respect to the total mass of the treatment liquid.

The content of the above-described polymer is preferably 0.1% to 30.0% by mass and more preferably 1.0% to 20.0% by mass with respect to the total mass of components in the treatment liquid excluding a solvent.

### <Polyhydroxy Compound Having Molecular Weight of 500 or More>

The polyhydroxy compound having a molecular weight of 500 or more is a compound different from the above-described compounds which can be contained in the treatment liquid.

The above-described polyhydroxy compound is an organic compound having 2 or more (for example, 2 to 200) alcoholic hydroxyl groups in one molecule.

A molecular weight (in a case of having a molecular weight distribution, a weight-average molecular weight) of the above-described polyhydroxy compound is 500 or more, preferably 500 to 100,000 and more preferably 500 to 3,000.

As the polyhydroxy compound, compounds exemplified in paragraphs [0101] and [0102] of WO2022/014287A can be used, the contents of which are incorporated herein by reference.

### <Oxidant>

Examples of the oxidant include a peroxide, a persulfide (for example, a monopersulfate or a dipersulfate), a percarbonate, an acid thereof, and a salt thereof.

Examples of the oxidant also include an oxidative halide (a periodic acid such as iodic acid, metaperiodic acid, and orthoperiodic acid, and salts thereof), a perboric acid, a perboric acid salt, a cerium compound, and a ferricyanide (potassium ferricyanide or the like).

### [Physical Properties of Treatment Liquid]

Hereinafter, properties of the treatment liquid will be described in detail.

<pH>

The pH of the treatment liquid is more than 7.0. That is, the treatment liquid exhibits basicity.

From the viewpoint that the effect of the present invention is more excellent, the pH of the treatment liquid is preferably 8.0 or more, more preferably 9.0 or more, still more preferably 10.0 or more, and particularly preferably 11.0 or more. The upper limit thereof is not particularly limited, but is preferably 14.0 or less, and more preferably 13.0 or less.

The pH of the treatment liquid can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, Al, Cr, Ni, Zn, Sn, and Ag) contained as impurities in the treatment liquid is preferably 5 mass ppm or less, and more preferably 1 mass ppm or less. It is assumed that, in manufacturing of a cutting-edge semiconductor element, a treatment liquid having even higher purity is required, and thus a metal content of the treatment liquid is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples thereof include lining an interior wall of the pipe with a fluororesin to prevent the elution of metal components from a pipe or the like during the production of the treatment liquid.

### <Abrasive Particles>

It is preferable that the treatment liquid does not substantially contain abrasive particles.

The abrasive particles mean particles which are contained in a polishing liquid used for performing a polishing treatment on a semiconductor substrate and have an average primary particle diameter of 5 nm or more.

Examples of the above-described abrasive particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

The expression “does not substantially contain the abrasive particles” means that the content of the abrasive particles is less than 0.1% by mass, preferably 0.01% by mass or less, and more preferably 0.001% by mass or less with respect to the total mass of the treatment liquid. The lower limit thereof is not particularly limited, and is 0% by mass.

The content of the abrasive particles can be measured using a commercially available measuring device in a light scattering type liquid particle measuring method using a laser as a light source.

In addition, an average primary particle diameter of particles such as abrasive particles is determined by measuring particle diameters (equivalent circle diameter) of 1,000 primary particles randomly selected from an image obtained using a transmission electron microscope TEM2010 (acceleration voltage: 200 kV) manufactured by JEOL Ltd., and calculating an arithmetic mean thereof. The equivalent circle diameter is a diameter of a virtual perfect circle assumed to have the same projected area as the projected area of particles observed.

Examples of a method for removing the abrasive particles from the treatment liquid include a purification treatment such as filtering.

### <Coarse Particles>

The treatment liquid may contain coarse particles, but it is preferable that a content thereof is preferably low.

The coarse particles mean particles having a diameter (particle size) of 0.03 m or more, in a case where a shape of the particles is regarded as a sphere.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The content of the coarse particles in the treatment liquid, in terms of content of particles having a particle size of 0.1 m or more, is preferably 10,000 or less and more preferably 5,000 or less per 1 mL of the treatment liquid. The lower limit thereof is preferably 0 or more, and more preferably 0.01 or more per milliliter of the treatment liquid.

The content of the coarse particles present in the treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### [Production Method]

The treatment liquid can be produced by a known method. Hereinafter, a production method of the treatment liquid will be described in detail.

### [Liquid Preparation Step]

The treatment liquid can be produced, for example, by mixing the above-described components.

Examples of the method for preparing the treatment liquid include a method in which the specific compound and the optional component as necessary are sequentially charged into a container containing purified pure water, the mixture is stirred and mixed, and a pH adjuster is added as necessary to adjust the pH of the mixed solution, thereby preparing the treatment liquid. In addition, in a case where the respective components are charged into the container, the respective components may be charged at once, or may be charged in a divided manner a plurality of times.

As a stirring device and a stirring method used for preparing the treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the treatment liquid, a refining treatment described later, and storage of the produced treatment liquid are preferably performed at 40° C. or lower, and more preferably performed at 30° C. or lower. The lower limit thereof is preferably 5° C. or higher and more preferably 10° C. or higher. By preparing, treating, and/or storing the treatment liquid in the above-described temperature range, stable performance can be maintained for a long period of time.

### <Purification>

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the stock solution is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, reprecipitation, distillation of a raw material, and filtering.

The purification treatment may be carried out by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyarylsulfone (PAS), polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the contents of which are incorporated herein by reference.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Dilution Step]

The above-described treatment liquid may be used for treating an object to be treated, as a diluted treatment liquid after undergoing a dilution step of diluting the treatment liquid using a diluent such as water.

The diluted treatment liquid is also an aspect of the treatment liquid according to the embodiment of the present invention as long as it satisfies the requirements of the present invention.

It is preferable to subject the diluent which is used in the dilution step to a purification treatment in advance. In addition, it is more preferable that the diluted treatment liquid obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the treatment liquid above, and it is preferable to carry out any one of these treatments.

A dilution rate of the treatment liquid in the dilution step may be appropriately adjusted depending on the type and content of each component and the object to be treated, but the ratio (dilution rate) of the diluted treatment liquid to the treatment liquid before the dilution is preferably 10 to 10,000 times, more preferably 20 to 3,000 times, still more preferably 50 to 1,000 times, and particularly preferably 50 to 500 times in terms of mass ratio or volume ratio (volume ratio at 23° C.).

In addition, from the viewpoint of more excellent cleanability, the treatment liquid is preferably diluted with water (preferably, ultrapure water).

It is preferable that the pH of the treatment liquid before the dilution and the pH of the diluted treatment liquid are each in the above-described suitable aspect.

A change in pH before and after the dilution (a difference between the pH of the treatment liquid before the dilution and the pH of the diluted treatment liquid) is preferably 2.0 or less, more preferably 1.8 or less, and still more preferably 1.5 or less.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### [Use Application]

The treatment liquid according to the embodiment of the present invention can be used for various materials used in the manufacturing of a semiconductor.

The above-described treatment liquid can be used, for example, for treating an insulating film, a resist, an antireflection film, an etching residue, an ashing residue, and the like present on a substrate, and is preferably used as a cleaning liquid.

In addition, the above-described treatment liquid is preferably used for an object to be treated (particularly, a semiconductor substrate), which has been subjected to a chemical mechanical polishing (CMP) treatment, and it is more preferable to be used in a cleaning step of cleaning the object to be treated, which has been subjected to a CMP treatment.

As described above, in a case where the treatment liquid is used, the treatment liquid may be used as a diluted treatment liquid obtained by diluting the treatment liquid.

Hereinafter, the object to be treated of the treatment liquid according to the embodiment of the present invention will be described in detail.

### [Object to be Treated]

Examples of the object to be treated with the treatment liquid include an object to be treated containing a metal; and a semiconductor substrate containing a metal is preferable.

In a case where the semiconductor substrate contains a metal, for example, the metal may be present on any of front and back surfaces, side surfaces, inside of a groove, and the like of the semiconductor substrate. In addition, in a case where the semiconductor substrate contains a metal, the metal includes not only a case in which the metal is directly present on the surface of the semiconductor substrate, but also a case in which the metal is present on the semiconductor substrate through another layer.

Examples of the above-described metal include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), niobium (Nb), and iridium (Ir); and at least one metal selected from the group consisting of Cu, Co, Ru, Mo, and W is preferable, at least one metal selected from the group consisting of Cu and Co is more preferable, and Cu is still more preferable. That is, as the object to be treated, an object to be treated containing at least one selected from the group consisting of Cu and Co is preferable, and an object to be treated containing Cu is more preferable.

The metal is preferably present as a metal layer containing a metal. Examples of a form of the metal contained in the metal layer include a simple substance of the metal M and an alloy containing the metal M.

Among these, the object to be treated preferably has a metal layer containing the metal M, more preferably has a metal layer containing Cu, Co, Ru, Mo, or W, still more preferably has a metal layer containing Cu or Co, and particularly preferably has a metal layer containing Cu.

Examples of a metal layer containing Cu (Cu-containing film) include a wire film consisting of only metal copper (copper wire film), and a wire film made of an alloy consisting of metal copper and another metal (a copper alloy wire film).

Examples of a copper alloy wire film include a wire film made of an alloy consisting of at least one metal selected from the group consisting of Al, Ti, Cr, Mn, Ta, Nb, and W, and Cu. More specific examples thereof include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), a copper-niobium alloy wire film (CuNb alloy wire film), and a copper-tungsten alloy wire film (CuW alloy wire film).

Examples of a metal layer containing Co (Co-containing film) include a metal film consisting of only metal cobalt (cobalt metal film), and a metal film made of an alloy consisting of metal cobalt and another metal (cobalt alloy metal film).

Examples of a cobalt alloy metal film include a metal film made of an alloy consisting of at least one metal selected from the group consisting of Ti, Cr, Fe, Ni, Mo, Pd, Ta, Nb, and W, and Co. More specific examples thereof include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), a cobalt-niobium alloy metal film (a CoNb alloy metal film), and a cobalt-tungsten alloy metal film (a CoW alloy metal film).

The object to be treated with the treatment liquid may have, for example, a semiconductor substrate, an insulating film, and a barrier metal, in addition to the above-described metal wire film.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film, a black diamond (BD) film, and a silicon carbide (SiC) film); and a low-dielectric-constant (Low-k) film is preferable.

Examples of the barrier metal include tantalum (Ta), tantalum nitride (TaN), titanium nitride (TiN), tungsten (W), tungsten alloy (tungsten-titanium (WTi) alloy, tungsten-cobalt (WCo) alloy, and the like), cobalt (Co), cobalt alloy, ruthenium (Ru), and ruthenium alloy.

A method of forming the insulating film, the copper-containing film, the cobalt-containing film, and the like described above on the wafer constituting the semiconductor substrate is not particularly limited as long as it is a method generally carried out in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the copper-containing film and the cobalt-containing film include a method of forming a circuit on the wafer having the above-described insulating film by a known method such as a resist, and then forming the metal layer by a method such as plating, a physical vapor deposition (PVD) method, and a CVD method. The object to be treated may have a layer for forming the copper-containing film or the cobalt-containing film on the above-described insulating layer.

### <CMP Treatment>

The treatment liquid is preferably used for an object to be treated, which has been subjected to a CMP treatment, and the object to be treated is more preferably an object to be treated containing a metal, which has been subjected to a CMP treatment, and still more preferably a semiconductor substrate containing a metal, which has been subjected to a CMP treatment.

The CMP treatment is a treatment in which a surface of the substrate having a layer selected from the metal wire film, the barrier metal, and the insulating film is flattened by a combined action of a chemical action and a mechanical polishing using a polishing slurry containing abrasive particles (abrasive grains).

A surface of the object to be treated which has been subjected to the CMP treatment may have residues such as abrasive grains (for example, silica and alumina) used in the CMP treatment, a polished metal wire film, and/or metal impurities (metal residue) derived from the barrier metal. In addition, an organic substance derived from a CMP treatment liquid used in the CMP treatment may remain as the residues. For example, since these residues may cause a short-circuit between wiring lines and deteriorate electrical characteristics of the semiconductor substrate, the semiconductor substrate which has been subjected to the CMP treatment is subjected to a cleaning treatment for removing these residues from the surface.

The treatment liquid according to the embodiment of the present invention is preferably used as a cleaning liquid for the cleaning treatment after the CMP treatment as described above.

Specific examples of the object to be treated, which has been subjected to the CMP treatment, include substrates which have been subjected to the CMP treatment, described in Journal of the Japan Society for Precision Engineering, Vol. 84, No. 3, 2018, but the present invention is not limited thereto.

<Object to be Treated which has been Subjected to Pad Cleaning Treatment>

The surface of the object to be treated may be subjected to a pad cleaning treatment after the CMP treatment.

The pad cleaning treatment is a treatment of reducing residues present on the surface of the object to be treated using a pad. Specifically, the surface of the object to be treated, which has been subjected to the CMP treatment, is brought into contact with the pad, and the object to be treated and the pad are relatively slid while supplying a composition for pad cleaning to a contact portion. As a result, the residues on the surface of the object to be treated are removed by a frictional force of the pad and the chemical action of the composition for pad cleaning.

The above-described pad is not particularly limited, and can be appropriately selected depending on the type of the object to be treated, the type of residues to be removed, and the device to be used. As the pad, a polishing pad used in the CMP treatment may be used, or a buff pad such as a foamed polyurethane-based buff pad, a nonwoven fabric, a suede-based buff pad, and a sponge may be used. The pad cleaning treatment using the pad includes a treatment called buff cleaning or buff polishing.

As the above-described composition for pad cleaning, a known cleaning composition can be used depending on the type of the object to be treated and the type and amount of the residues to be removed. Examples of components contained in the composition for pad cleaning include a water-soluble polymer such as polyvinyl alcohol, a dispersion medium such as water, and an acid such as nitric acid. In addition, the composition for pad cleaning does not contain abrasive particles.

The device and conditions used in the pad cleaning treatment can be appropriately selected from known devices and conditions depending on the type of the treatment object and the type and amount of the residues to be removed. For example, a treatment method described in paragraphs [0085] to [0088] of WO2017/169539A can be used, the contents of which are incorporated herein by reference.

In addition, as one embodiment of the pad cleaning treatment, it is also preferable to perform a pad cleaning treatment on the object to be treated, using the treatment liquid according to the embodiment of the present invention as the composition for pad cleaning.

The treatment liquid to be subjected to the pad cleaning treatment may be a diluted treatment liquid.

The pad cleaning treatment may be performed only once or may be performed twice or more. For example, after the CMP treatment, the object to be treated may be subjected to a pad cleaning treatment using a polishing pad and a pad cleaning treatment using a buff pad.

### [Method of Using Treatment Liquid]

The treatment liquid can be used by a known method. Hereinafter, a method of using the treatment liquid will be described in detail.

### [Treatment Step]

Examples of the method of using the treatment liquid include a treatment method for an object to be treated, which includes a step of bringing the object to be treated into contact with the treatment liquid. Hereinafter, the step of bringing the object to be treated into contact with the treatment liquid is also referred to as “contact step”.

The method of bringing the object to be treated into contact with the treatment liquid is not particularly limited; and examples thereof include a method of immersing the object to be treated in the treatment liquid contained in a tank, a method of spraying the treatment liquid onto the object to be treated, a method of flowing the treatment liquid onto the object to be treated, and a combination thereof. The above-described method may be appropriately selected depending on the purpose.

In addition, the above-described method may appropriately adopt a method usually performed in the field. For example, scrub cleaning in which a cleaning member such as a brush is physically brought into contact with a surface of the object to be treated while supplying the treatment liquid to remove residues and the like, spinning (dropping) cleaning in which the treatment liquid is dropped while rotating the object to be treated, or the like may be used. From the viewpoint that impurities remaining on a surface of the object to be treated can be further reduced, it is preferable that the object to be treated immersed in the treatment liquid is subjected to an ultrasonic treatment.

The contact between the object to be treated and the treatment liquid in the contact step may be carried out only once or twice or more. In a case of carrying out the contact twice or more, the same method may be repeated or different methods may be combined.

The treatment method of the object to be treated may be a single-wafer method or a batch method. The single-wafer method is a method of treating one object to be treated at a time; and the batch method is a method of treating a plurality of objects to be treated at the same time.

A temperature of the treatment liquid is not particularly limited, but from the viewpoint of more excellent cleanability and further suppressing damage to the member, it is preferably 10° C. to 60° C. and more preferably 15° C. to 50° C.

It is preferable that a pH of the treatment liquid and a pH of the diluted treatment liquid are each in the above-described suitable aspect of pH.

A contact time between the object to be treated and the treatment liquid may be appropriately changed depending on the type and content of each component contained in the treatment liquid, the use target and purpose of the treatment liquid, but it is preferably 10 to 120 seconds, more preferably 20 to 90 seconds, and still more preferably 30 to 60 seconds.

A supply amount (supply rate) of the treatment liquid is preferably 50 to 5,000 mL/min, and more preferably 500 to 2,000 mL/min.

In the contact step, a mechanical stirring method may be used in order to further improve the cleaning ability of the treatment liquid.

Examples of the mechanical stirring method include a method of circulating the treatment liquid on the object to be treated, a method of flowing or spraying the treatment liquid on the object to be treated, and a method of stirring the treatment liquid with ultrasonic wave or megasonic wave.

It is preferable that the above-described treatment step is a cleaning step of removing residues on the surface of the object to be treated by bringing the object to be treated into contact with the treatment liquid. A preferred aspect of the cleaning step is the same as the preferred aspect of the contact step described above.

In addition, after the contact step, a step of bringing the object to be treated into contact with a rinsing liquid (hereinafter, also referred to as “rinsing step”) may be performed. By performing the rinsing step, the object to be treated, obtained in the contact step, is washed with a rinsing liquid, and the residues can be efficiently removed.

The rinsing step is preferably a step which is carried out continuously subsequently after the cleaning step of the semiconductor substrate, in which the object to be treated is rinsed with a rinsing liquid. The rinsing step may be performed using the above-described mechanical stirring method.

Examples of the rinsing liquid include water (preferably, DI water), methanol, ethanol, isopropyl alcohol (IPA), N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As the method in which the rinsing liquid is brought into contact with the object to be treated, the method in which the treatment liquid is brought into contact with the object to be treated can be similarly applied.

A contact time between the object to be treated and the rinsing liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

After the contact step and/or the rinsing step described above, a drying step of drying the object to be treated may be performed.

Examples of the drying method include a spin drying method, a method of flowing a dry gas onto the object to be treated, a method of heating a substrate by a heating unit such as a hot plate and an infrared lamp, a Marangoni drying method, a Rotagoni drying method, an IPA drying method, and a method of combining any of these methods.

### [Manufacturing Method of Electronic Device]

The above-described treatment method for an object to be treated can be suitably applied to a manufacturing process of an electronic device.

The above-described treatment method may be performed in combination before or after other steps performed on a substrate. The above-described treatment method may be incorporated into other steps while performing the treatment method, or the above-described treatment method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described treatment method may be performed at any stage among the back-end process (BEOL: back end of the line), the middle process (MOL: middle of the line), and the front-end process (FEOL: front end of the line); and it is preferable that the treatment method be performed in a front-end process or a middle process.

### EXAMPLES

Hereinbelow, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

In the following Examples, a pH of the treatment liquid was measured at 25° C. using a pH meter (manufactured by HORIBA, Ltd., model “F-74”) in accordance with JIS Z 8802-1984.

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Raw Materials of Treatment Liquid]

The following compounds were used to produce a treatment liquid. As various components used in Examples and Comparative Examples, those all classified into a semiconductor grade or a high-purity grade equivalent thereto were used.

### [Specific Compound]

N-methylethylenediamine
N-ethylethylenediamine
N,N-dimethylethylenediamine
2-aminomethylpiperidine

### [Purine Compound]

Adenine (corresponding to the compound represented by Formula (C5))
Xanthine (corresponding to the compound represented by Formula (C7))
Adenosine (corresponding to the compound represented by Formula (C5))
6-Benzyladenine (corresponding to the compound represented by Formula (C5))
Kinetin (corresponding to the compound represented by Formula (C5))
Hypoxanthine (corresponding to the compound represented by Formula (C6))
Methyladenine (corresponding to the compound represented by Formula (C5))

### [Tertiary Amine Compound X and Quaternary Ammonium Compound]

ETMAH: ethyltrimethylammonium hydroxide (quaternary ammonium compound)
   PMDETA: N,N,N′,N″,N″-pentamethyldiethylenetriamine (tertiary amine compound X)
DMAMP: 2-(dimethylamino)-2-methyl-1-propanol (tertiary amine compound X)

### [Anionic Polymer]

Polyacrylic acid (manufactured by TOAGOSEI CO., LTD., Aron A-10SL)
   Acrylic acid-sulfonic acid-based monomer copolymer (manufactured by Nippon Shokubai Co., Ltd., AQUALIC GL-366)

### [Comparative Compound]

Monoethanolamine
2-(2-aminoethylamino)ethanol
Ethylenediamine

In the treatment liquid, the remaining component (remainder) other than components specified as the components of the treatment liquid in the tables was ultrapure water.

### [Production of Treatment Liquid]

A production method of the treatment liquid will be described.

The above-described compounds were added with the blending amounts shown in the following tables, and sufficiently stirred to obtain a concentrated solution. The obtained concentrated solution was diluted with ultrapure water as a diluent at a dilution ratio (volume ratio) described in the column of the dilution ratio in the following tables, thereby obtaining a treatment liquid of each of Examples and Comparative Examples.

### [Evaluation of Treatment Liquid]

Anticorrosion properties and cleanability in a case of being brought into contact with an object to be treated containing Cu or Co were evaluated for the treatment liquid produced by the above-described method. Hereinafter, the evaluation method will be described.

### [Anticorrosion Properties]

A Cu or Co wafer of 2×2 cm was prepared, placed in a container filled with the treatment liquid of each of Examples or Comparative Examples, and immersed at room temperature (25° C.) for 30 minutes. Thereafter, contents of Cu or Co in the immersed treatment liquid were measured by Agilent 8800 triple quadrupole ICP-MS (for semiconductor analysis, option #200) to determine an etching rate.

The anticorrosion properties were evaluated according to the following evaluation standard. As the etching rate is lower, the corrosion of the metal is more suppressed, leading to excellent anticorrosion properties, which is more preferable. With regard to the anticorrosion properties, it is preferable to be evaluated as C or higher.
A: less than 0.4 Å/min
B: 0.4 Å/min or more and less than 0.6 Å/min
C: 0.6 Å/min or more and less than 0.8 Å/min
D: 0.8 Å/min or more
   [Cleanability after CMP Treatment]

Cleanability for organic residues was evaluated in a case where a semiconductor substrate subjected to a CMP treatment was cleaned using the treatment liquid produced by the above-described method.

Using FREX300S-II (polishing device, manufactured by EBARA CORPORATION), a wafer (diameter: 12 inches) having a Cu film or a Co film on a surface was polished under conditions in which a polishing liquid 1 was used as a polishing liquid, an in-plane average value of a polishing pressure was 105 hPa, a supply rate of the polishing liquid was 200 mL/min, and a polishing time was 30 seconds. Next, the wafer subjected to the above-described polishing treatment was further polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained wafer subjected to the CMP treatment was subjected to scrub cleaning for 1 minute using the treatment liquid of each of Examples and Comparative Examples, adjusted to room temperature (23° C.), and then subjected to a drying treatment.

Formulations of the polishing liquid 1 and the polishing liquid 2 described above were as follows.

Polishing liquid 1 (pH: 7.0)

| | | |
|---|---|---|
| Colloidal silica (PL3, manufactured by | 0.1% | by mass |
| FUSO CHEMICAL CO., LTD.) | | |
| Glycine | 1.0% | by mass |
| 3-Amino-1,2,4-triazole | 0.2% | by mass |
| 5-methyl-benzotriazole (5mBTA) | 30 | mass ppm |
| Hydrogen peroxide | 1.0% | by mass |

| | |
|---|---|
| pH adjuster (ammonia and nitric acid) | |
| Water | remainder |

Polishing liquid 2 (pH: 10.5)

| | | |
|---|---|---|
| Colloidal silica (PL3, manufactured by | 6.0% | by mass |
| FUSO CHEMICAL CO., LTD.) | | |
| Citric acid | 1.0% | by mass |
| Alkylalkoxylate surfactant | 100 | mass ppm |
| 5mBTA | 0.2% | by mass |
| Hydrogen peroxide | 1.0% | by mass |

| | |
|---|---|
| pH adjuster (potassium hydroxide and nitric acid) | |
| Water | remainder |

Next, a defect detection device (ComPlus-II, manufactured by AMAT) was used to measure the number of detections of signal intensities corresponding to defects having a length of more than 0.1 m on the obtained polished surface of the wafer. Thereafter, each defect was observed with a scanning electron microscope (SEM), and the constituent elements were specified as a measurement target with an energy dispersive X-ray spectroscopy (EDX) device as necessary.

From the above, the number of defects (number of target defects) based on organic residues (residues containing an organic substance as a main component) on the polished surface of the wafer was determined.

The cleanability was evaluated according to the following evaluation standard. As the number of target defects detected on the polished surface of the wafer is smaller, the cleanability for the organic residues is excellent, which is more preferable. With regard to the cleanability, it is preferable to be evaluated as C or higher.
A: number of target defects was 30 or less.
B: number of target defects was more than 30 and 50 or less.
C: number of target defects was more than 50 and 70 or less.
D: number of target defects was more than 70.

### Result

The formulations of the treatment liquids of Examples and the evaluation results are shown in Tables 1 to 3.

In the tables, the column of “Content (% by mass” indicates the content (% by mass) of each component with respect to the total mass of the concentrated solution.

In the tables, the column of (I)/(II) indicates the mass ratio of the content of the (I) specific compound to the content of the (II) purine compound (Content of specific compound/Content of purine compound).

In the tables, the column of (I)/(III) indicates the mass ratio of the content of the (I) specific compound to the total content of the (III) tertiary amine compound X and quaternary ammonium compound ((Content of specific compound)/(Content of tertiary amine compound X+Content of quaternary ammonium compound)).

In the tables, the column of “Dilution ratio” indicates the dilution ratio (volume ratio) of the concentrated solution in a case of preparing the treatment liquid as described above.

In the tables, the numerical value in the column of pH indicates the pH of the treatment liquid at 25° C., which was measured by the above-described pH meter. The above-described pH is a value measured for the treatment liquid prepared by diluting the concentrated solution.

Table 3 is a continuation of Table 2. For example, the treatment liquid of Example 23 is a treatment liquid containing adenine, N-ethylethylenediamine, DMAMP, and polyacrylic acid, in which the pH is 10.9 the dilution ratio is 100.

TABLE 1

| | Semiconductor treatment liquid | | | | | | | |
|---|---|---|---|---|---|---|---|---|
| | | | | | (III) Tertiary amine compound X and | | | |
| | (II) Purine compound | | (I) Specific compound | | quaternary ammonium compound | | | |
| | | Content | | Content | | Content | | Content |
| | | (% by | | (% by | | (% by | | (% by |
| | Type | mass) | Type | mass) | Type | mass) | Type | mass) |
| Example 1 | Adenine | 0.204 | 2-Aminomethylpiperidine | 0.015 | ETMAH | 1.74 | PMDETA | 0.86 |
| Example 2 | Xanthine | 0.038 | N-Ethylethylenediamine | 0.044 | ETMAH | 1.74 | PMDETA | 1.67 |
| Example 3 | Adenine | 0.038 | 2-Aminomethylpiperidine | 0.056 | ETMAH | 1.74 | PMDETA | 1.67 |
| Example 4 | Adenine | 0.038 | N-Methylethylenediamine | 0.037 | ETMAH | 1.74 | PMDETA | 1.67 |
| Example 5 | Adenine | 0.012 | 2-Aminomethylpiperidine | 0.132 | ETMAH | 1.74 | PMDETA | 1.67 |
| Example 6 | Adenosine | 0.038 | 2-Aminomethylpiperidine | 0.056 | ETMAH | 1.74 | PMDETA | 1.67 |
| Example 7 | 6-Benzyladenine | 0.038 | 2-Aminomethylpiperidine | 0.056 | ETMAH | 1.74 | PMDETA | 1.67 |
| Example 8 | Xanthine | 0.038 | 2-Aminomethylpiperidine | 0.056 | ETMAH | 1.74 | PMDETA | 1.67 |
| Example 9 | Xanthine | 0.038 | N,N-Dimethyl- | 0.044 | ETMAH | 1.74 | PMDETA | 1.67 |
| | | | ethylenediamine | | | | | |
| Example 10 | Adenine | 0.038 | N-Ethylethylenediamine | 0.044 | ETMAH | 1.74 | PMDETA | 1.67 |
| Example 11 | Kinetin | 0.038 | 2-Aminomethylpiperidine | 0.056 | ETMAH | 1.74 | PMDETA | 1.67 |
| Example 12 | Adenine | 0.038 | 2-Aminomethylpiperidine | 0.012 | DMAMP | 5.70 | PMDETA | 1.00 |
| Example 13 | Xanthine | 0.038 | 2-Aminomethylpiperidine | 0.056 | ETMAH | 1.74 | — | — |
| Example 14 | Adenine | 0.038 | N,N-Dimethyl- | 0.044 | ETMAH | 1.74 | PMDETA | 1.67 |
| | | | ethylenediamine | | | | | |
| Example 15 | Adenine | 0.038 | 2-Aminomethylpiperidine | 0.056 | ETMAH | 1.74 | PMDETA | 1.67 |
| Example 16 | Adenine | 0.038 | 2-Aminomethylpiperidine | 0.056 | ETMAH | 1.74 | — | — |
| Example 17 | Adenine | 0.038 | 2-Aminomethylpiperidine | 0.056 | DMAMP | 5.70 | PMDETA | 1.00 |
| Example 18 | Adenine | 0.038 | 2-Aminomethylpiperidine | 0.056 | ETMAH | 1.74 | PMDETA | 1.67 |
| Example 19 | Xanthine | 0.038 | N-Methylethylenediamine | 0.037 | ETMAH | 1.74 | PMDETA | 1.67 |
| Example 20 | Methyladenine | 0.038 | 2-Aminomethylpiperidine | 0.056 | ETMAH | 1.74 | PMDETA | 1.67 |
| Example 21 | Adenine | 0.038 | 2-Aminomethylpiperidine | 0.220 | ETMAH | 1.00 | PMDETA | 0.17 |
| Example 22 | Hypoxanthine | 0.038 | 2-Aminomethylpiperidine | 0.056 | ETMAH | 1.74 | PMDETA | 1.67 |
| Comparative | Hypoxanthine | 0.038 | — | — | DMAMP | 5.70 | PMDETA | 1.00 |
| Example 1 | | | | | | | | |
| Comparative | Hypoxanthine | 0.038 | Monoethanolamine | 0.030 | ETMAH | 1.74 | PMDETA | 1.67 |
| Example 2 | | | | | | | | |
| Comparative | Hypoxanthine | 0.038 | 2-(2-Aminoethyl- | 0.051 | DMAMP | 5.70 | PMDETA | 1.00 |
| Example 3 | | | amino)ethanol | | | | | |
| Comparative | Hypoxanthine | 0.038 | Ethylenediamine | 0.044 | ETMAH | 1.74 | PMDETA | 1.67 |
| Example 4 | | | | | | | | |

| | | | | | Evaluation | | | |
|---|---|---|---|---|---|---|---|---|
| | Semiconductor treatment liquid | | | | | | Anticorrosion | |
| | | | Dilution | | Cleanability | | properties | |
| | (I)/(II) | (I)/(III) | ratio | pH | Cu | Co | Cu | Co |
| Example 1 | 0.07 | 0.0058 | 100 | 11.3 | B | B | A | A |
| Example 2 | 1.16 | 0.0129 | 100 | 11.3 | B | B | B | B |
| Example 3 | 1.47 | 0.0164 | 50 | 11.4 | A | A | A | A |
| Example 4 | 0.97 | 0.0109 | 100 | 11.3 | A | A | A | A |
| Example 5 | 11.00 | 0.0387 | 100 | 11.3 | A | A | B | B |
| Example 6 | 1.47 | 0.0164 | 100 | 11.3 | A | A | A | A |
| Example 7 | 1.47 | 0.0164 | 100 | 11.3 | A | A | A | A |
| Example 8 | 1.47 | 0.0164 | 100 | 11.3 | A | A | A | A |
| Example 9 | 1.16 | 0.0129 | 100 | 11.3 | A | A | A | A |
| Example 10 | 1.16 | 0.0129 | 100 | 11.3 | B | B | B | B |
| Example 11 | 1.47 | 0.0164 | 100 | 11.3 | A | A | A | A |
| Example 12 | 0.32 | 0.0018 | 100 | 11.0 | B | B | A | A |
| Example 13 | 1.47 | 0.0322 | 100 | 11.3 | A | A | A | A |
| Example 14 | 1.16 | 0.0129 | 100 | 11.3 | A | A | A | A |
| Example 15 | 1.47 | 0.0164 | 150 | 11.2 | A | A | A | A |
| Example 16 | 1.47 | 0.0322 | 100 | 11.2 | A | A | A | A |
| Example 17 | 1.47 | 0.0084 | 100 | 11.0 | A | A | A | A |
| Example 18 | 1.47 | 0.0164 | 100 | 11.3 | A | A | A | A |
| Example 19 | 0.97 | 0.0109 | 100 | 11.3 | A | A | A | A |
| Example 20 | 1.47 | 0.0164 | 100 | 11.3 | A | A | A | A |
| Example 21 | 5.79 | 0.1880 | 100 | 11.0 | A | A | B | B |
| Example 22 | 1.47 | 0.0164 | 100 | 11.3 | B | B | B | B |
| Comparative | — | — | 100 | 11.0 | D | D | B | B |
| Example 1 | | | | | | | | |
| Comparative | 0.79 | 0.0088 | 100 | 11.3 | D | D | C | C |
| Example 2 | | | | | | | | |
| Comparative | 1.34 | 0.0076 | 100 | 11.0 | B | B | D | D |
| Example 3 | | | | | | | | |
| Comparative | 1.16 | 0.0129 | 100 | 11.3 | B | B | D | D |
| Example 4 | | | | | | | | |

TABLE 2

| | Semiconductor treatment liquid | | | | | | | |
|---|---|---|---|---|---|---|---|---|
| | | | | | (III) Tertiary amine compound X and | | | |
| | (II) Purine compound | | (I) Specific compound | | quaternary ammonium compound | | | |
| | | Content | | Content | | Content | | Content |
| | | (% by | | (% by | | (% by | | (% by |
| | Type | mass) | Type | mass) | Type | mass) | Type | mass) |
| Example 23 | Adenine | 0.038 | N-Ethylethylenediamine | 0.441 | DMAMP | 5.70 | — | — |
| Example 24 | Adenine | 0.038 | 2-Aminomethylpiperidine | 0.056 | DMAMP | 5.70 | — | — |
| Example 25 | Adenine | 0.038 | 2-Aminomethylpiperidine | 0.056 | ETMAH | 1.74 | — | — |
| Example 26 | Xanthine | 0.038 | 2-Aminomethylpiperidine | 0.056 | ETMAH | 1.74 | — | — |
| Example 27 | Xanthine | 0.038 | 2-Aminomethylpiperidine | 0.056 | ETMAH | 1.74 | — | — |
| Example 28 | Xanthine | 0.038 | 2-Aminomethylpiperidine | 0.056 | ETMAH | 1.74 | PMDETA | 1.67 |
| Example 29 | Kinetin | 0.038 | 2-Aminomethylpiperidine | 0.056 | ETMAH | 1.74 | PMDETA | 1.67 |
| Example 30 | Hypoxanthine | 0.038 | 2-Aminomethylpiperidine | 0.056 | ETMAH | 1.74 | PMDETA | 1.67 |

TABLE 3

| | | | | | | | Evaluation | | | |
|---|---|---|---|---|---|---|---|---|---|---|
| | | | | | (IV) Anionic polymer | | | | | |
| | | | | | | Content | | | Anticorrosion | |
| | | | Dilution | | | (% by | Cleanability | | properties | |
| | (I)/(II) | (I)/(III) | ratio | pH | Type | mass) | Cu | Co | Cu | Co |
| Example 23 | 11.61 | 0.0774 | 100 | 10.9 | Polyacrylic acid | 0.363 | A | A | C | C |
| Example 24 | 1.47 | 0.0098 | 100 | 10.9 | Polyacrylic acid | 0.363 | A | A | A | A |
| Example 25 | 1.47 | 0.0322 | 100 | 11.2 | Polyacrylic acid | 0.363 | A | A | A | A |
| Example 26 | 1.47 | 0.0322 | 100 | 11.2 | Polyacrylic acid | 0.363 | A | A | A | A |
| Example 27 | 1.47 | 0.0322 | 100 | 11.2 | Acrylic acid-sulfonic | 0.100 | A | A | A | A |
| | | | | | acid-based monomer | | | | | |
| | | | | | copolymer | | | | | |
| Example 28 | 1.47 | 0.0164 | 100 | 11.3 | Acrylic acid-sulfonic | 0.100 | A | A | A | A |
| | | | | | acid-based monomer | | | | | |
| | | | | | copolymer | | | | | |
| Example 29 | 1.47 | 0.0164 | 100 | 11.3 | Acrylic acid-sulfonic | 0.100 | A | A | A | A |
| | | | | | acid-based monomer | | | | | |
| | | | | | copolymer | | | | | |
| Example 30 | 1.47 | 0.0164 | 100 | 11.3 | Acrylic acid-sulfonic | 0.100 | A | A | B | B |
| | | | | | acid-based monomer | | | | | |
| | | | | | copolymer | | | | | |

From the results in Table 1, it was found that the treatment liquid according to the embodiment of the present invention had excellent anticorrosion properties and excellent cleanability for organic residues in a case where the treatment liquid was brought into contact with an object to be treated containing a metal, which had been subjected to a chemical mechanical polishing treatment.

On the other hand, from the results of Comparative Examples, it was found that the treatment liquid not containing the specific compound did not satisfy the target level of at least one of the cleanability or the anticorrosion properties, and thus it was not possible to achieve both the anticorrosion properties and the cleanability.

From the comparison of Examples 6 to 8, 11, 18, 20, and 22, it was found that, in a case where the purine compound included at least one compound selected from the group consisting of the compound represented by Formula (C5) and the compound represented by Formula (C7), the effect of the present invention was more excellent.

From the comparison of Examples 1, 5, and 18, it was found that, in a case where the mass ratio of the content of the specific compound to the content of the purine compound was 0.1 or more, the cleanability was more excellent, and in a case where the mass ratio was 10.0 or less, the anticorrosion properties were more excellent.

From the comparison of Examples 12, 18, and 21, it was found that, in a case where the mass ratio of the content of the specific compound to the total content of the quaternary ammonium compound and the above-described tertiary amine compound was 0.005 or more, the cleanability was more excellent, and in a case where the mass ratio was 0.15, the anticorrosion properties were more excellent.

From the comparison of Examples 2, 4, 8 to 10, 13 to 14, 18 to 19, and 22, it was found that, in a case where the specific compound was a compound in which, in Formula (1), the group represented by R¹ and R² was a methyl group, or R¹ and R² or R¹ and R³ were bonded to each other through a single bond or a divalent linking group to form a ring, the effect of the present invention was more excellent.

From the comparison of Examples 3, 15, and 18, it was found that the effect of the present invention was excellent even in a case where the dilution ratio of the treatment liquid was different.

[Cleanability after Pad Cleaning Treatment]

A wafer was prepared according to the procedure described in [Cleanability after CMP treatment] above, and subjected to a CMP treatment.

The polished surface of the wafer subjected to the CMP treatment was subjected to a pad cleaning treatment under the following conditions using FREX300S-II (polishing device, manufactured by EBARA CORPORATION).

| Table rotation speed: | 80 | rpm |
|---|---|---|
| Head rotation speed: | 78 | rpm |
| In-plane average value of pad | 138 | hPa |
| pressure: | | |
| Polishing pad: | IC1400 manufactured by Rodel-Nitta | |
| Composition for pad cleaning: | treatment liquid used in Example 1 | |
| Supply rate of composition for | 250 | mL/min |
| pad cleaning: | | |
| Polishing time: | 20 | seconds |

The obtained wafer subjected to the pad cleaning treatment was subjected to scrub cleaning for 1 minute using the treatment liquid used in Example 1, adjusted to room temperature (23° C.), and then subjected to a drying treatment. Thereafter, as a result of evaluation according to [Cleanability after CMP treatment], the same evaluation results as those of Example 1 were obtained.

Even in a case where the treatment liquids used in Examples 2 to 30 were used instead of the treatment liquid used in Example 1 described above, the same evaluation results as the evaluation results of each of Examples were obtained.

What is claimed is:

1. A semiconductor treatment liquid comprising:
a compound represented by Formula (1),
wherein a pH of the semiconductor treatment liquid is more than 7.0, 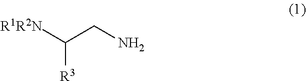
R¹ to R³ each independently represent a hydrogen atom or an alkyl group which may have a substituent other than a hydroxyl group, where at least one of R¹ or R² represents the alkyl group which may have a substituent other than a hydroxyl group, and
at least two selected from R¹ to R³ may be bonded to each other through a single bond or a divalent linking group to form a ring.

2. The semiconductor treatment liquid according to claim 1,
wherein the pH is 10.0 or more.

3. The semiconductor treatment liquid according to claim 1, further comprising:
at least one purine compound selected from the group consisting of purine and a purine derivative.

4. The semiconductor treatment liquid according to claim 3,
wherein the purine compound includes at least one compound selected from the group consisting of a compound represented by Formula (C5) and a compound represented by Formula (C7), 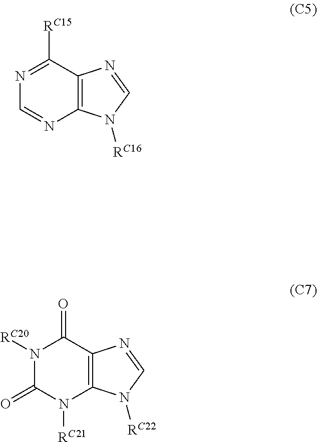
in Formula (C5), R^{C15} and R^{C16} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent,
in Formula (C7), R^{C20} to R^{C22} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

5. The semiconductor treatment liquid according to claim 1, further comprising:
at least one compound selected from the group consisting of a tertiary amine compound different from the compound represented by Formula (1), and a quaternary ammonium compound.

6. The semiconductor treatment liquid according to claim 3,
wherein a mass ratio of a content of the compound represented by Formula (1) to a content of the purine compound is 0.1 to 10.0.

7. The semiconductor treatment liquid according to claim 5,
wherein a mass ratio of a content of the compound represented by Formula (1) to the total content of the tertiary amine compound different from the compound represented by Formula (1) and the quaternary ammonium compound is 0.005 to 0.15.

8. The semiconductor treatment liquid according to claim 1, further comprising:
an anionic polymer.

9. The semiconductor treatment liquid according to claim 1,
wherein the semiconductor treatment liquid is used as a cleaning liquid.

10. The semiconductor treatment liquid according to claim 1,
wherein the semiconductor treatment liquid is used for an object to be treated, which has been subjected to a chemical mechanical polishing treatment.

11. The semiconductor treatment liquid according to claim 1,
wherein the semiconductor treatment liquid is used for an object to be treated containing at least one metal selected from the group consisting of Cu and Co.

12. The semiconductor treatment liquid according to claim 1,
wherein the semiconductor treatment liquid is used for an object to be treated containing at least one metal selected from the group consisting of Cu and Co, which has been subjected to a chemical mechanical polishing treatment.

13. A treatment method for an object to be treated, comprising:
a step of bringing an object to be treated containing at least one metal selected from the group consisting of Cu and Co, which has been subjected to a chemical mechanical polishing treatment, into contact with the semiconductor treatment liquid according to claim 1.

14. A manufacturing method of an electronic device, comprising:
the treatment method for an object to be treated according to claim 13.

15. The semiconductor treatment liquid according to claim 2, further comprising:
at least one purine compound selected from the group consisting of purine and a purine derivative.

16. The semiconductor treatment liquid according to claim 15,
wherein the purine compound includes at least one compound selected from the group consisting of a compound represented by Formula (C5) and a compound represented by Formula (C7), 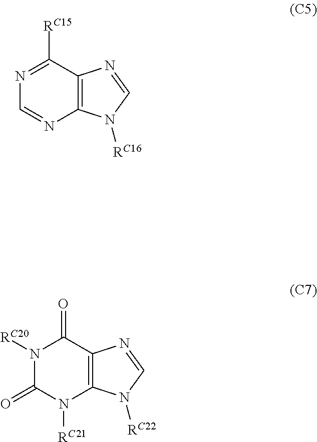
in Formula (C5), R^{C15} and R^{C16} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent,
in Formula (C7), R^{C20} to R^{C22} each independently represent a hydrogen atom, an alkyl group which may have a substituent, an amino group which may have a substituent, a thiol group, a hydroxyl group, a halogen atom, a sugar group which may have a substituent, or a polyoxyalkylene group-containing group which may have a substituent.

17. The semiconductor treatment liquid according to claim 2, further comprising:
at least one compound selected from the group consisting of a tertiary amine compound different from the compound represented by Formula (1), and a quaternary ammonium compound.

18. The semiconductor treatment liquid according to claim 15,
wherein a mass ratio of a content of the compound represented by Formula (1) to a content of the purine compound is 0.1 to 10.0.

19. The semiconductor treatment liquid according to claim 17,
wherein a mass ratio of a content of the compound represented by Formula (1) to the total content of the tertiary amine compound different from the compound represented by Formula (1) and the quaternary ammonium compound is 0.005 to 0.15.

20. The semiconductor treatment liquid according to claim 2, further comprising:
an anionic polymer.
